(19) United States
(12) Patent Application Publication
(10) Pub. No.: US 2008/0296714 A1
(43) Pub. Date: Dec. 4, 2008

(54) Wafer level package of image sensor and method for manufacturing the same

(75) Inventors: Jingli Yuan, Suwon (KR); Won Kvu Jeung, Seoul (KR); Dae Jun Kim, Suwon (KR); Chang Hyun Lim, Suwon (KR); Young Do Kweon, Seoul (KR); Jae Cheon Doh, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/155,267

(22) Filed: May 30, 2008

(30) Foreign Application Priority Data
May 31, 2007 (KR) 10-2007-0053552

(51) Int. Cl. H01L 31/0232; H01L 31/18

(52) U.S. Cl. 257/432; 438/69; 257/E31.127; 257/E21.002

(57) ABSTRACT

Provided is a wafer level package of an image sensor capable of simply and easily packaging an image sensor in a packaging process, and a method for manufacturing the same. The wafer level package of an image sensor includes a lower substrate including an image sensor, a conductive pattern coupled to the image sensor, and a plurality of vias coupled to the conductive pattern; a micro lens array film having a plurality of micro lenses corresponding to the image sensor, the micro lenses being formed on the lower substrate; and a sealing line surrounding the image sensor while being spaced apart from the image sensor and being in contact with an upper substrate. The wafer level package may be useful to have an electrical connection structure using vias without any need to a bonding wire, an electrode pad and an electrode lead in the conventional wafer level package since a packaging process is carried out by bonding a wafer for an upper substrate with a plurality of the vias being provided in a wafer for a lower substrate

### CROSS-REFERENCE TO RELATED APPLICATIONS

This application claims the priority of Korean Patent Application No. 2007-53552 filed on May 31, 2007, in the Korean Intellectual Property Office, the disclosure of which is incorporated herein by reference.

### BACKGROUND OF THE INVENTION

1. Field of the Invention

The present invention relates to a wafer level package of an image sensor and a method for manufacturing the same, and more particularly, to a wafer level package of an image sensor capable of simply and easily packaging an image sensor in a packaging process, and a method for manufacturing the same.

2. Description of the Related Art

A semiconductor package protects a circuit block since the circuit block is formed on a device substrate and a cap substrate is covered with the semiconductor package, the cap substrate including an external electrode and a through-hole electrode, both of which are electrically coupled to the circuit block.

Since this semiconductor package is sensitive to the external environments, the semiconductor package has been used as a SAW filter including an IDT electrode and an image sensor having an image focusing region, the IDT electrode being necessarily cutoff from the external environments. Also, there has been proposed a method for manufacturing these components at a wafer level for the purpose of their miniaturization.

For the above-mentioned conventional wafer level package, an image sensor 13 is formed in an upper surface of a semiconductor substrate 11 including semiconductor devices as shown in FIG. 1 by packaging image sensors such as, for example, a CCD image sensor and a CMOS image sensor, and a micro lens block 14 is formed on the image sensor 13.

The other surface of the semiconductor substrate 11 has a box-type container 15 attached to the bottom thereof by an adhesive 17, the box-type container 15 being formed of ceramics or synthetic resins. And, since an opening of the box-type container 15 is sealed by mounting the glass cover 12 using an adhesive 19, the image sensor 13 and the micro lens block 14 arranged inside the box-type container 15 are protected from the external environments.

Also, an electrode lead 16 extracted out from the box-type container 15 is in electrical contact with an electrode pad 9 by means of the bonding wire 18, the electrode pad 9 being provided on a surface of the semiconductor substrate 11.

However, the wafer level package of the image sensor requires a space for contacting the electrode lead 16 with the electrode pad 9 using the bonding wire 18.

Furthermore, since the image sensor 13 is shielded from the light, a bonding wire 18, an electrode pad 9 and the like may not be disposed on the image sensor 13 or the micro lens block 14. Therefore, it is difficult to manufacture a small wafer level package of the image sensor through this simple process.

### SUMMARY OF THE INVENTION

The present invention is designed to solve the problems of the prior art, and therefore it is an object of the present invention to provide a wafer level package having a simple electrical connection structure to an image sensor.

Also, it is another object of the present invention to provide a method for manufacturing a wafer level package of an image sensor in which an image sensor is packaged into a miniaturized wafer level package through a simple process.

According to an aspect of the present invention, there is provided a wafer level package of an image sensor including a lower substrate including an image sensor, a conductive pattern coupled to the image sensor, and a plurality of vias coupled to the conductive pattern; a micro lens array film having a plurality of micro lenses corresponding to the image sensor, the micro lenses being formed on the lower substrate; and a sealing line surrounding the image sensor while being spaced apart from the image sensor and being in contact with an upper substrate.

According to another aspect of the present invention, there is also provided a method for manufacturing a wafer level package of an image sensor, the method including: forming an image sensor, a plurality of conductive patterns and vias on a wafer for a lower substrate, the conductive patterns being coupled to the image sensor and the vias coupled to the conductive pattern and having a predetermined depth; forming a micro lens array film on the wafer for a lower substrate including the vias, the micro lens array film including a plurality of micro lenses corresponding the image sensor; bonding an upper substrate onto the micro lens array film along a sealing line disposed spaced apart from the image sensor and surrounding the image sensor; performing a thinning process to reduce a thickness of the wafer for a lower substrate including the vias; and performing a dicing process in which the image sensor surrounded by the sealing line and the package including the vias are separated from each other.

In this case, the wafer level package according to the present invention may further include a passivation layer formed between the lower substrate and the micro lens array film, the passivation layer being formed of one film selected from the group consisting of a silicon dioxide film (SiO₂), an oxide film (PSG) and a silicon nitride film.

Also, the upper substrate may be a transparent substrate made of a transparent material.

In addition, the sealing line may be made of one material selected from the group consisting of benzo cyclo butene (BCB), dry film resin (DFR), epoxy and thermosetting polymer.

Additionally, the micro lens array film may be formed of transparent resin such as polycarbonate (PC) or silicon epoxy.

Also, in the forming vias, the predetermined depth of the vias may be formed more deeply than the final thickness of the wafer for a lower substrate, or be formed equally to a penetration depth of the wafer for a lower substrate.

In addition, the forming vias may include: forming a plurality of via holes in an etching process using a photoresist pattern to expose an end region of the conductive pattern; and forming vias by filling the via holes with a metal.

Additionally, the forming vias may include: forming a plurality of via holes using a mechanical method to drill an end region of the conductive pattern; and forming vias by filling the via holes with a metal.

Furthermore, the performing a dicing process may be carried out along a cut line that is spaced apart from the vias and penetrated through the sealing line to the wafer for a lower substrate, the cut line being formed on the wafer for an upper substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a conventional image sensor package.

FIG. 2 is a cross-sectional view illustrating a wafer level package of an image sensor according to one exemplary embodiment of the present invention.

FIGS. 3A to 3F are process cross-sectional views illustrating a method for manufacturing a wafer level package of an image sensor according to one exemplary embodiment of the present invention.

### DETAILED DESCRIPTION OF THE PREFERRED EMBODIMENT

Exemplary embodiments of the present invention will now be described in detail with reference to the accompanying drawings.

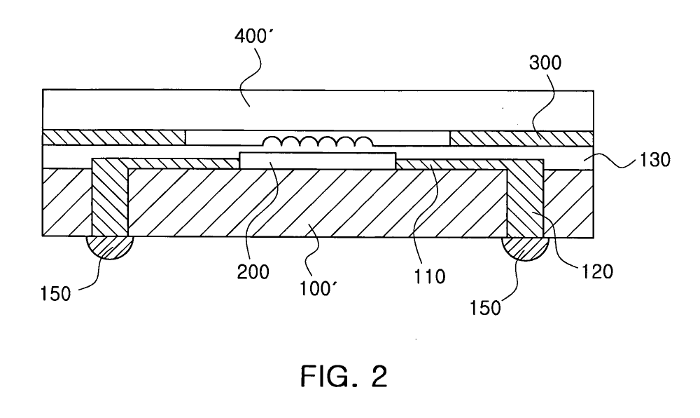

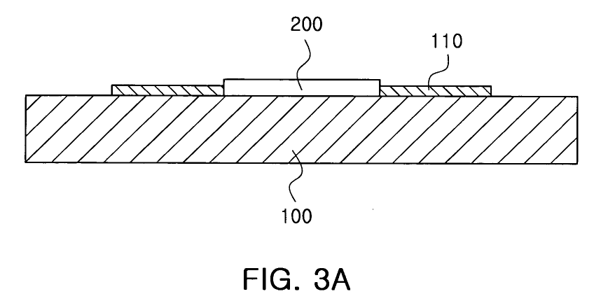

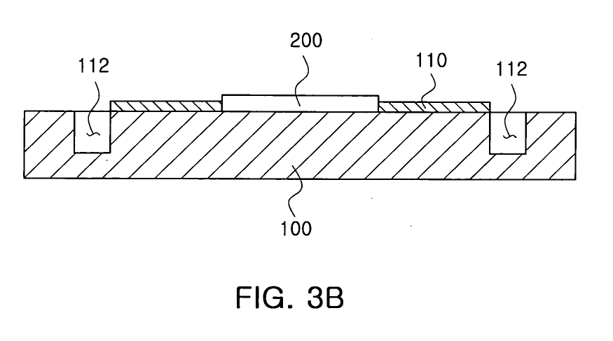

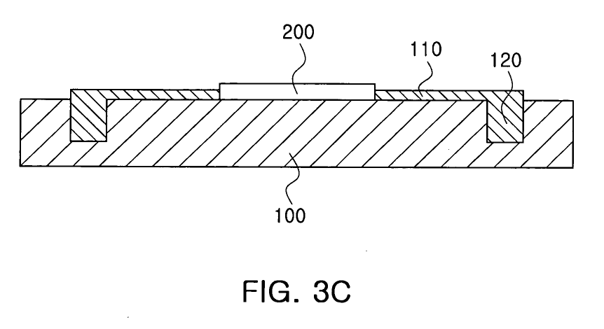

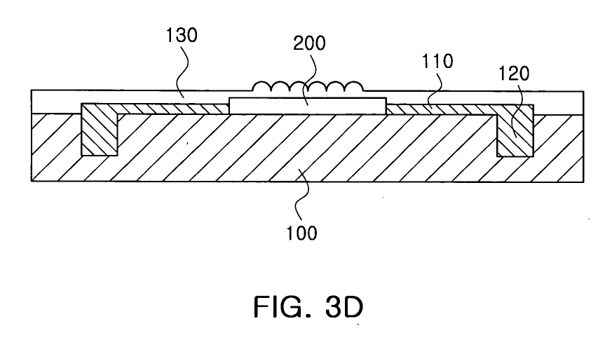

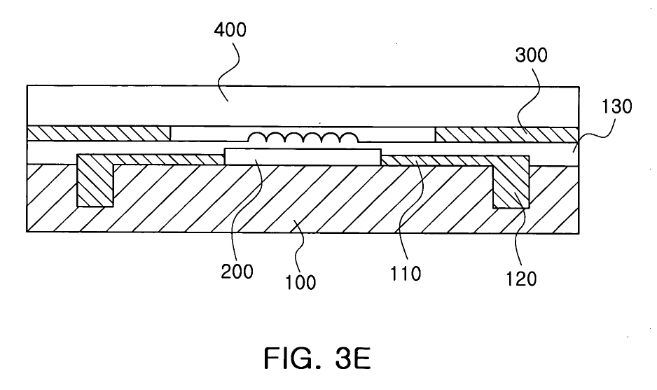

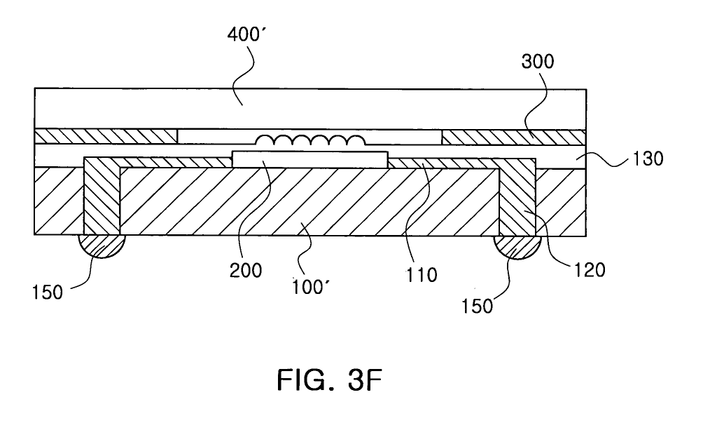

FIG. 2 is a cross-sectional view illustrating a wafer level package of an image sensor according to one exemplary embodiment of the present invention, and FIGS. 3A to 3F are process cross-sectional views illustrating a method for manufacturing a wafer level package of an image sensor according to one exemplary embodiment of the present invention.

As shown in FIG. 2, the wafer level package of an image sensor according to one exemplary embodiment of the present invention has an image sensor 200 mounted therein, and includes a lower substrate 100′ having a plurality of vias 120 coupled respectively to conductive patterns 110; a micro lens array film 130 having a plurality of micro lenses formed on the image sensor 200; and a sealing line 300 formed on the micro lens array film 130 to surround the image sensor 200 while being spaced apart from the image sensor 200 and being in contact with an upper substrate 400.′

The lower substrate 100′ has an image sensor 200 mounted in an upper surface thereof as a semiconductor substrate, and includes a plurality of conductive patterns 110 coupled to the image sensor 200 and patterned with a metallic material; and vias 120 coupled respectively to the conductive patterns 110. Here, solders 150 are provided in lower surfaces of the vias 120, and mounted in an apparatus, for example a camera module, in which a package is mounted, which leads to the electrical contact of the solders 150 with the camera module.

The micro lens array film 130 is a member provided with a plurality of light-focusing lenses corresponding to the image sensor 200. In this case, the micro lens array film 130 is formed of transparent resin, for example, polycarbonate (PC), silicon epoxy and the like, to give transparency and light-concentrating effect. Here, because a member, which is prepared by selectively spreading impurities over a glass substrate, may be used as the micro lens array film 130, the glass substrate having a lens effect may be used as the micro lens array film 130 due to the refractive-index dispersion characteristics at the presence of impurities.

Also, prior to selectively provide the micro lens array film 130 in the image sensor 200, a passivation layer (not shown) is provided in a lower surface of the micro lens array film 130 to protect the image sensor 200 in a wafer level packaging process, the passivation layer being formed of a film such as a silicon dioxide film (SiO₂), an oxide film (PSG), a silicon nitride film, etc.

The sealing line 300, in the form of a closed curve, is provided to surround a plurality of lenses corresponding to the image sensor 200, and may be provided by screen-printing a polymer such as benzo cyclo butene (BCB), dry film resin (DFR), epoxy, thermosetting polymer, or injecting the polymer through a nozzle.

As a transparent substrate such as a glass substrate that is made of a transparent material, the upper substrate 400′ is bonded to the micro lens array film 130 by means of a sealing line 300 provided onto the micro lens array film 130.

As described above, the wafer level package of an image sensor according to one exemplary embodiment of the present invention may be configured, compared to the conventional electrical connection structure, by applying a power source supplied from the outside to the image sensor 200 through the vias 120, or deducing an electrical signal from the image sensor 200.

Hereinafter, the method for manufacturing a wafer level package of an image sensor according to one exemplary embodiment of the present invention will be described in detail with reference to FIGS. 3A to 3F.

The method for manufacturing a wafer level package of an image sensor according to one exemplary embodiment of the present invention first is first carried out by mounting an image sensor 200 in the wafer 100 for a lower substrate and patterning a plurality of conductive patterns 110 coupled to the image sensor 200, as shown in FIG. 3A.

In this case, a plurality of the conductive patterns 110 is formed of metallic materials, for example, through a patterning process of forming a metal film using a physical vapor deposition (PVD) process and etching the metal film.

After the image sensor 200 and the conductive pattern 110 are provided on the wafer 100 for a lower substrate, via holes 112, each having a predetermined depth, are formed in ends of the conductive patterns 110 by employing a mechanical method such as an etching process or a drilling process using first photoresist patterns (not shown) that are provided onto the image sensor 200 and the conductive patterns 110 to expose end regions of the conductive patterns 110, as shown in FIG. 3B.

More particularly, the via holes 112 each having a predetermined depth may be formed using the etching process that includes a wet etching process or a dry etching process such as a reactive ion etching (RIE) process. Also, the via holes 112 may be formed using the mechanical method such as a drilling process when the via holes 112 have a high diameter. In this case, the via holes 112 may be formed at a higher depth than a thickness of a lower substrate 100′ of a package to be finally manufactured.

Also, the via holes 112 are formed to have a predetermined depth for the wafer 100 for a lower substrate, as shown in FIG. 3B, but the present invention is not particularly limited thereto. Therefore, it is also possible to form the via holes 112 through the wafer 100 for a lower substrate.

After the formation of the via holes 112, vias 120 are formed by filling the via holes 112 with a metal, as shown in FIG. 3C.

To form the vias 120 as shown in FIG. 3C, a second photoresist pattern (not shown) is used to cover the image sensor 200 and the conductive patterns 110 and expose the via holes 112, and the via holes are filled with an electrically conductive metal and the electrically conductive metal is deposited for the connection with the conductive patterns 110 in a physical vapor deposition (PVD) process using a second photoresist pattern.

After the via holes 112 are filled and the electrically conductive metal is deposited for the connection with the conductive patterns 110, the vias 120 coupled to the conductive patterns 110 are formed by removing the second photoresist pattern, as shown in FIG. 3C. When the vias 120 are formed, a micro lens array film 130 is provided onto the image sensor 200 to form a plurality of micro lenses, as shown in FIG. 3D.

The micro lens array film 130 is formed of transparent resin such as polycarbonate (PC) or silicon epoxy, which is used for a lens material, for example may be formed by pressing the lens material at a low temperature. A glass material prepared by selectively dispersing impurities is used for the micro lens array film 130 to have a lese effect due to the refractive-index dispersion characteristics at the presence of impurities

Prior to selectively forming the micro lens array film 130, the micro lens array film 130 may also be formed on the passivation layer when the passivation layer is further provided to protect the image sensor 200. In this case, the passivation layer, which may be formed in a lower surface of the micro lens array film 130, may be formed of one film to protect the image sensor 200 in the wafer level packaging process, the one film being selected from the group consisting of a silicon dioxide film (SiO₂), an oxide film (PSG) and a silicon nitride film.

After the formation of the micro lens array film 130, a sealing line 300 surrounding one region of the image sensor 200 is formed on the micro lens array film 130, as shown in FIG. 3E.

The sealing line 300 is provided by screen-printing a polymer such as benzo cyclo butene (BCB), dry film resin (DFR), epoxy, thermosetting polymer, or injecting the polymer through a nozzle, and may be provided in the form of a closed curve to surround one region of the image sensor 200 in the micro lens array film 130.

After the formation of the sealing line 300, a wafer 400 for a transparent upper substrate is bonded at a temperature of 80 to 150C using the sealing line 300 formed of a polymer, and therefore one region of the image sensor 200 in the micro lens array film 130 is sealed with the wafer 400 for an upper substrate by means of the sealing line 300, as shown in FIG. 3E.

After the wafer 400 for an upper substrate is provided using the sealing line 300 as described above, the wafer 100 for a lower substrate is subject to a chemical mechanical polishing (CMP) process to expose a plurality of the vias 120 by grinding a lower surface of the wafer 100 for a lower substrate flatly so as to reduce its thickness.

In this case, the operation of grinding the wafer 100 for a lower substrate in the CMP process is carried out to the extent to expose a plurality of the vias 120 and the extent to which the package has a final thinner thickness.

Therefore, after a thickness of the wafer 100 for a lower substrate is reduced through the CMP process to expose a plurality of the vias 120, a dicing process is carried out to prepare packages, each of which includes the vias 120 and the image sensor 200 surrounded by the sealing line 300.

More particularly, the dicing process may be carried out by cutting along a cut line (not shown) formed on the wafer 400 for an upper substrate to be spaced apart from the vias 120 and penetrated to the wafer for a lower substrate through the sealing line 300.

When the wafer level packages including the image sensor 200 and the via 120 is separately prepared though the dicing process, each of the wafer level packages may have a connection structure in which a power source supplied from the outside is applied to the image sensor 200 through the vias 120, or an electrical signal is deduced from the image sensor 200 by forming solders 150 in the exposed vias 120 to mount the wafer level package in other apparatus such as a camera module, as shown in FIG. 3F.

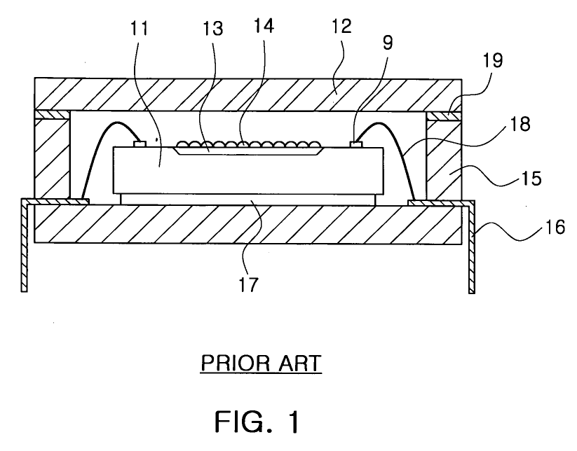

For the method for manufacturing a wafer level package of a wafer level according to one exemplary embodiment of the present invention, the wafer level package is manufactured by bonding the wafer 400 for an upper substrate with a plurality of the vias 120 being provided in the wafer 100 for a lower substrate, and therefore the wafer level package has an electrical connection structure formed through the vias 120 without any need to the bonding wire 18, the electrode pad 9, the electrode lead 16 and the like as shown in FIG. 1

Also, since the wafer 100 for a lower substrate having a plurality of the vias 120 is subject to the CMP process to manufacture a lower substrate 100′ having a desired thickness, the wafer level package of an image sensor may be easily manufactured at a small and thin scale.

As described above, the wafer level package according to the present invention may be useful to have an electrical connection structure using the vias without any need to a bonding wire, an electrode pad and an electrode lead in the conventional wafer level package since a packaging process is carried out by bonding the wafer for an upper substrate with a plurality of the vias being provided in the wafer for a lower substrate.

Also, the method for manufacturing wafer level package according to the present invention may be useful to manufacture a small and thin wafer level package of an image sensor in an easy manner since the wafer for a lower substrate including a plurality of vias may be subject to the CMP process to manufacture a lower substrate having a desired thickness.

While the present invention has been shown and described in connection with the exemplary embodiments, it will be apparent to those skilled in the art that modifications and variations can be made without departing from the spirit and scope of the invention as defined by the appended claims.

What is claimed is:

1. A wafer level package of an image sensor, comprising:
a lower substrate including an image sensor, a conductive pattern coupled to the image sensor, and a plurality of vias coupled to the conductive pattern;
a micro lens array film having a plurality of micro lenses corresponding to the image sensor, the micro lenses being formed on the lower substrate; and
a sealing line surrounding the image sensor while being spaced apart from the image sensor and being in contact with an upper substrate.

2. The wafer level package of claim 1, further comprising a passivation layer formed between the lower substrate and the micro lens array film, the passivation layer being formed of one film selected from the group consisting of a silicon dioxide film (SiO₂), an oxide film (PSG) and a silicon nitride film.

3. The wafer level package of claim 1, wherein the upper substrate is a transparent substrate made of a transparent material.

4. The wafer level package of claim 1, wherein the sealing line is made of one material selected from the group consisting of benzo cyclo butene (BCB), dry film resin (DFR), epoxy and thermosetting polymer.

5. The wafer level package of claim 1, wherein the micro lens array film is formed of transparent resin such as polycarbonate (PC) or silicon epoxy.

6. A method for manufacturing a wafer level package of an image sensor, the method comprising:
forming an image sensor, a plurality of conductive patterns and vias on a wafer for a lower substrate, the conductive patterns being coupled to the image sensor and the vias being coupled to the conductive pattern and having a predetermined depth;
forming a micro lens array film on the wafer for a lower substrate including the vias, the micro lens array film including a plurality of micro lenses corresponding the image sensor;
bonding an upper substrate onto the micro lens array film along a sealing line disposed spaced apart from the image sensor and surrounding the image sensor;
performing a thinning process to reduce a thickness of the wafer for a lower substrate including the vias; and
performing a dicing process in which the image sensor surrounded by the sealing line and the package including the vias are separated from each other.

7. The method of claim 6, further comprising: forming a passivation layer on the wafer for a lower substrate including the vias between the forming vias and the forming a micro lens array film, the passivation layer being formed of one film selected from the group consisting of a silicon dioxide film (SiO₂), an oxide film (PSG) and silicon nitride film.

8. The method of claim 6, wherein the predetermined depth of the vias is formed more deeply than the final thickness of the wafer for a lower substrate in the forming vias.

9. The method of claim 6, wherein the predetermined depth of the vias is formed equally to a penetration depth of the wafer for a lower substrate in the forming vias.

10. The method of claim 6, wherein the forming vias comprises:
forming a plurality of via holes in an etching process using a photoresist pattern to expose an end region of the conductive pattern; and
forming vias by filling the via holes with a metal.

11. The method of claim 6, wherein the forming vias comprises:
forming a plurality of via holes using a mechanical method to drill an end region of the conductive pattern; and
forming vias by filling the via holes with a metal.

12. The method of claim 6, wherein the sealing line is made of one material selected from the group consisting of benzo cyclo butene (BCB), dry film resin (DFR), epoxy and thermosetting polymer.

13. The method of claim 6, wherein the performing a dicing process is carried out along a cut line that is spaced apart from the vias and penetrated through the sealing line to the wafer for a lower substrate, the cut line being formed on the wafer for an upper substrate.

14. The method of claim 6, wherein the upper substrate is a transparent substrate made of a transparent material.
